(19) United States
(12) Patent Application Publication
(10) Pub. No.: US 2020/0044414 A1
(43) Pub. Date: Feb. 6, 2020

(54) OPTICAL TRANSMITTER, OPTICAL TRANSCEIVER, AND METHOD OF MANUFACTURING OPTICAL TRANSMITTER

(71) Applicant: Sumitomo Electric Industries, Ltd., Osaka-shi, Osaka (JP)

(72) Inventors: Tomoyuki FUNADA, Osaka-shi, Osaka (JP); Daisuke KAWASE, Osaka-shi, Osaka (JP)

(73) Assignee: Sumitomo Electric Industries, Ltd., Osaka-shi, Osaka (JP)

(21) Appl. No.: 16/467,561

(22) PCT Filed: Jul. 28, 2017
(86) PCT No.: PCT/JP2017/027473

§ 371 Date: Jun. 7, 2019

(30) Foreign Application Priority Data
Dec. 28, 2016 (JP) 2016-256477

(51) Int. Cl. H01S 5/0625; H01S 5/40; H01S 5/024; H01S 5/042; H01S 5/022; H04B 10/40; H04B 10/2563; H04B 10/572; H04J 14/02

(52) U.S. Cl. CPC H01S 5/06258; H01S 5/4087; H01S 5/02415; H01S 5/042; H01S 5/12; H04B 10/40; H04B 10/2563; H04B 10/572; H04J 14/02; H01S 5/02248

(57) ABSTRACT

An optical transmitter includes a plurality of light-emitting units each configured to transmit an optical signal having a different wavelength and change the wavelength of the optical signal. At least one light-emitting unit of the plurality of light-emitting units is configured to adjust the wavelength.

### TECHNICAL FIELD

The present invention relates to an optical transmitter, an optical transceiver, and a method of manufacturing an optical transmitter. The present application claims a priority based on Japanese Patent Application No. 2016-256477 filed on Dec. 28, 2016, the entire contents of which are incorporated herein by reference.

### BACKGROUND ART

The transmission capacity in optical communications has been dramatically increased. In recent years, optical communications with a transmission capacity of 100 Gbps have been proposed.

For example, in 100 Gigabit Ethernet (note that Ethernet is a registered trademark) or 100 G-Ethernet (registered trademark) passive optical network (EPON), four optical signals with a rate of 25.8 Gbps which have different wavelengths are transmitted. Specifically, the four optical signals are multiplexed in accordance with wavelength division multiplexing (WDM). Wavelength-multiplexed light is transmitted through an optical fiber.

When the zero-dispersion wavelength of an optical fiber and a plurality of wavelengths of a wavelength-multiplexed signal satisfy predetermined conditions, four-wave mixing occurs in the optical fiber. The light generated by four-wave mixing is superimposed on an optical signal of one channel of a plurality of channels, thereby triggering crosstalk noise. This may lead to degraded communication quality. As the power of an optical signal (wavelength-multiplexed light) is increased for long-distance transmission of an optical signal, a distortion of a signal due to four-wave mixing increases.

Japanese Patent Laying-Open No. 2007-5484 (PTL 1) discloses an optical amplifier aimed to reduce four-wave mixing. This optical amplifier includes an optical fiber that has positive wavelength dispersion in a signal band and amplifies a wavelength-multiplexed signal, and an excitation section that inputs excitation light to the optical fiber.

It is reported that an electroabsorption modulator integrated distributed feedback laser (EADFB laser) including integration of semiconductor optical amplifiers (SOAs) can reduce power consumption more and increase an optical output more than a conventional EADFB laser in Wataru Kobayashi and five others, October 2015, “Reduction of power consumption and extended transmission distance of EADFB laser by integrating SOA,” OSC 2015-78 (NPL 1), IEICE technical report, IEICE.

### CITATION LIST

### Patent Literature

PTL 1: Japanese Patent Laying-Open No. 2007-5484

### Non Patent Literature

NPL 1: Wataru Kobayashi and five others, October 2015, “Reduction of power consumption and extended transmission distance of EADFB laser by integrating SOA”, OSC 2015-78, IEICE technical report, IEICE.

### SUMMARY OF INVENTION

An optical transmitter according to an aspect of the present invention includes a plurality of light-emitting units each configured to transmit an optical signal having a different wavelength and change the wavelength of the optical signal, and a wavelength adjustment unit configured to individually adjust the wavelength of the optical signal per light-emitting unit.

### BRIEF DESCRIPTION OF DRAWINGS

FIG. 1 shows an example configuration of an optical communication system according to an embodiment.

FIG. 2 is a block diagram showing a schematic configuration regarding wavelength multiplexing communication in an embodiment.

FIG. 3 shows a schematic configuration of an optical transceiver applicable to the embodiment.

FIG. 4 is a block diagram schematically showing a configuration of an optical transmitter module 50 shown in FIG. 3.

FIG. 5 is a schematic view for illustrating a thermal connection among a laser diode, a submount, and a thermoelectric cooler which are shown in FIG. 4.

FIG. 6 shows an example relationship between a drive current and a center wavelength of laser light for a laser diode (DFB-LD) applicable to the embodiment.

FIG. 7 shows an example relationship between drive current and optical output for a laser diode (EA-DFB-LD) applicable to the embodiment.

FIG. 8 shows an example relationship between a reverse bias voltage to an EA modulator and a DC extinction ratio for a laser diode (EA-DFB-LD) applicable to the embodiment.

FIG. 9 is a block diagram showing an example configuration of a controller of an optical transceiver.

FIG. 10 shows an example of wavelength information.

FIG. 11 is a flowchart illustrating a method of manufacturing an optical transmitter according to the embodiment.

FIG. 12 is a schematic view showing an example configuration of a host board according to the embodiment.

FIG. 13 is a schematic view showing another example configuration of the host board according to the embodiment.

### DETAILED DESCRIPTION

### Problem to be Solved by the Present Disclosure

An object of the present disclosure is to reduce an effect of crosstalk noise due to four-wave mixing by an optical transmitter.

### Description of Embodiments

Embodiments of the present invention will initially be listed and described.

(1) An optical transmitter according to an aspect of the present invention includes a plurality of light-emitting units each configured to transmit an optical signal having a different wavelength. At least one light-emitting unit of the plurality of light-emitting units is configured to adjust the wavelength.

According to the above, an effect of crosstalk noise due to four-wave mixing can be reduced by the optical transmitter. At least one light-emitting unit of the plurality of light-emitting units is configured to adjust the wavelength of the optical signal. Adjusting the wavelength of the optical signal from the light-emitting unit allows each of the plurality of light-emitting units to transmit the optical signal such that a condition that causes a four-wave mixing distortion is not satisfied.

(2) Preferably, the optical transmitter further includes a thermoelectric cooler provided in common to the plurality of light-emitting units and configured to control temperatures of the plurality of light-emitting units, a plurality of thermal resistors thermally connected to the thermoelectric cooler, each of which is thermally connected to a corresponding one of the plurality of light-emitting units, and a current supply unit configured to individually supply a drive current to the plurality of light-emitting units.

According to the above, the plurality of light-emitting units are thermally isolated from each other by the thermal resistor. The temperature of each light-emitting unit can be controlled by the thermoelectric cooler and the thermal resistor. Changing the drive current supplied to the light-emitting unit capable of adjusting the wavelength changes the temperature of the light-emitting unit. Consequently, the wavelength of the optical signal output from the light-emitting unit can be adjusted.

(3) Preferably, each of the plurality of thermal resistors is a submount on which a corresponding one of the plurality of light-emitting units is mounted.

According to the above, the temperature of the light-emitting unit can be changed without an additional element such as a heater. A known material can be used as the material for the submount.

(4) Preferably, the current supply unit is configured to receive a control signal through an interface and change an operating point of the at least one light-emitting unit configured to adjust the wavelength.

According to the above, changing the operating point can change the wavelength of the optical signal output from the light-emitting unit capable of adjusting the wavelength. Consequently, an effect of a four-wave mixing distortion can be reduced.

(5) Preferably, the optical transmitter further includes an interface for outputting, to outside of the optical transmitter, wavelength information about the wavelength of the optical signal to be output from the at least one light-emitting unit configured to adjust the wavelength.

According to the above, information about the wavelength of the optical signal can be acquired from the optical transmitter through the interface. This enables, for example, determination of the presence or absence of an effect of four-wave mixing. This also eliminates the need for actually outputting light from the optical transmitter to measure the wavelength.

(6) Preferably, the optical transmitter further includes a storage unit configured to store an operating point of the at least one light-emitting unit configured to adjust the wavelength.

According to the above, at least one light-emitting unit capable of adjusting the wavelength can be controlled in accordance with the stored operating point. An effect of a four-wave mixing distortion can thus be reduced.

(7) An optical transceiver according to an aspect of the present invention includes an optical transmitter according to any one of (1) to (6) and an optical receiver.

According to the above, the optical transceiver capable of reducing an effect of a four-wave mixing distortion can be provided.

(8) A method of manufacturing an optical transmitter according to an aspect of the present invention is a method of manufacturing an optical transmitter including a plurality of light-emitting units each configured to transmit an optical signal having a different wavelength. At least one light-emitting unit of the plurality of light-emitting units is configured to adjust the wavelength. The method includes setting an operating point of the at least one light-emitting unit configured to adjust the wavelength such that the wavelength of the optical signal output from each of the plurality of light-emitting units is excluded from a condition that causes a four-wave mixing distortion, and causing the optical transmitter to store the operating point set in the setting.

According to the above, the optical transmitter capable of reducing a four-wave mixing distortion can be manufactured.

(9) An optical transmitter according to an aspect of the present invention includes a plurality of light-emitting units each configured to transmit an optical signal having a different wavelength. At least one light-emitting unit of the plurality of light-emitting units is configured to adjust the wavelength. The optical transmitter further includes a storage unit configured to store an operating point of the at least one light-emitting unit configured to adjust the wavelength for excluding, from a condition that causes a four-wave mixing distortion, the wavelength of the optical signal output from each of the plurality of light-emitting units.

According to the above, the optical transmitter capable of reducing an effect of a four-wave mixing distortion can be manufactured.

### Detailed Description of Embodiments

Embodiments of the present invention will be described hereinafter with reference to the drawings. The same or corresponding elements in the drawings have the same reference numerals allotted, and description thereof will not be repeated.

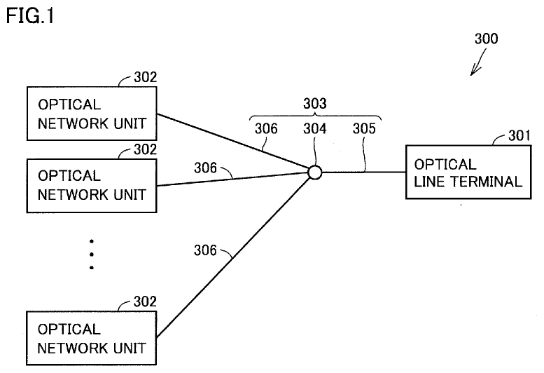

FIG. 1 shows an example configuration of an optical communication system according to an embodiment. In FIG. 1, a PON system 300 is an optical communication system according to one embodiment. PON system 300 includes an optical line terminal 301, optical network units 302, a PON line 303, and an optical splitter 304.

Optical line terminal (OLT) 301 is placed in an office of a communication common carrier. Optical line terminal 301 has a host board (not shown) mounted therein. The host board is connected with an optical transceiver (not shown) that converts an electric signal and an optical signal to each other.

Optical network unit (ONU) 302 is installed on the user side. Each of optical network units 302 is connected to optical line terminal 301 through PON line 303.

PON line 303 is an optical communication line composed of optical fibers. PON line 303 includes a trunk optical fiber 305 and at least one branch optical fiber 306. Optical splitter 304 is connected to trunk optical fiber 305 and branch optical fiber 306. Optical network units 302 can be connected to PON line 303.

An optical signal transmitted from optical line terminal 301 passes through PON line 303 and is branched to optical network units 302 by optical splitter 304. On the other hand, the respective optical signals transmitted from optical network units 302 are bundled by optical splitter 304 and transmitted to optical line terminal 301 through PON line 303. Optical splitter 304 passively branches or multiplexes signals input thereto, without requiring a specific external power supply.

As a high-rate PON system, a wavelength multiplexing PON system is studied that allocates a plurality of wavelengths to an upstream signal or a downstream signal and subjects the plurality of wavelengths to wavelength multiplexing to form an upstream signal or a downstream signal. For example, a 100 Gbps class PON can be configured to allocate four wavelengths of optical signals having a transmission capacity of 25.8 Gbps per wavelength to each of uplink and downlink and subject the optical signals to wavelength multiplexing.

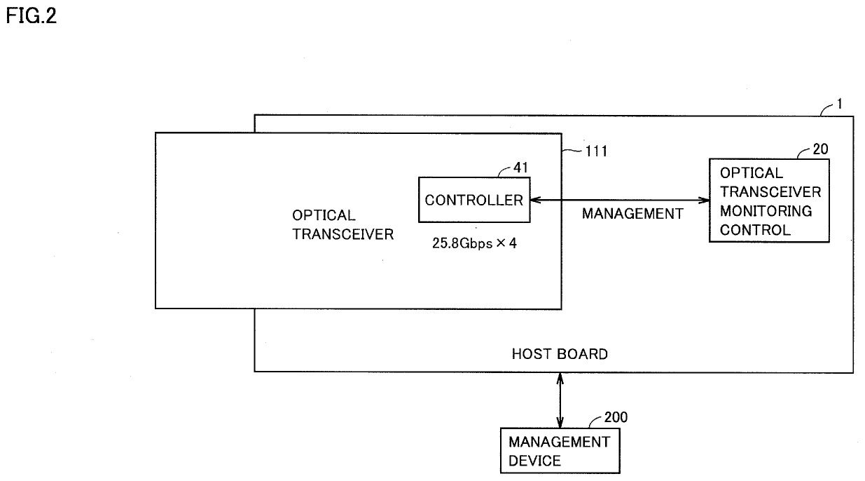

FIG. 2 is a block diagram showing a schematic configuration regarding wavelength multiplexing communication in one embodiment. With reference to FIG. 2, an optical transceiver 111 is mounted on a host board 1. Optical transceiver 111 is an optical transceiver with 25.8 Gbps×4 wavelengths. Optical transceiver 111 includes a controller 41 that controls the operation of optical transceiver 111.

Host board 1 has an optical transceiver monitoring control block 20. Optical transceiver monitoring control block 20 is configured by a semiconductor integrated circuit. Optical transceiver monitoring control block 20 can acquire information about at least one wavelength of wavelength-multiplexed light from optical transceiver 111 through a management interface. The wavelength information is stored in controller 41.

Optical transceiver monitoring control block 20 can transmit a control signal to controller 41 through the management interface. Controller 41 can adjust at least one wavelength of the wavelength-multiplexed light output from optical transceiver 111 in accordance with the control signal. Optical transceiver monitoring control block 20 may detect an abnormality of optical transceiver 111 based on the information output from optical transceiver 111. In this case, optical transceiver monitoring control block 20 may notify management device 200 of the occurrence of the abnormality. For example, when an effect of crosstalk noise (four-wave mixing distortion) due to four-wave mixing may be caused, optical transceiver monitoring control block 20 makes a notification to management device 200.

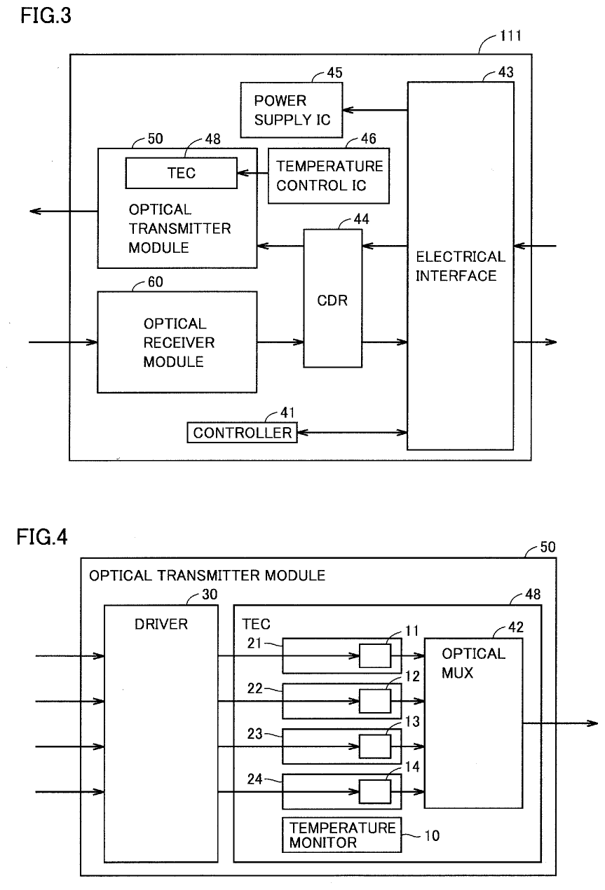

FIG. 3 shows a schematic configuration of an optical transceiver applicable to the present embodiment. As shown in FIG. 3, optical transceiver 111 includes controller 41, an electrical interface 43, a clock data recovery (CDR) IC 44, a power supply IC 45, a temperature control IC 46, an optical transmitter module 50, and an optical receiver module 60. In the present embodiment, optical receiver module 60 configures an optical receiver of the optical transceiver.

Controller 41 monitors and controls optical transceiver 111. Controller 41 can store information about the wavelength of the wavelength-multiplexed light output from optical transceiver 111. A memory that stores the information about the wavelength may be provided in optical transceiver 111 separately from controller 41. Controller 41 may be integrated with any other IC such as temperature control IC 46.

Electrical interface 43 inputs and outputs an electric signal. Optical transmitter module 50 outputs data from clock data recovery IC 44 in the form of an optical signal. Electrical interface 43 is an interface for outputting wavelength information from inside to outside of the optical transmitter. Electrical interface 43 is also an interface for receiving a control signal from outside of the optical transmitter. Optical transmitter module 50 is configured to change an operating point of at least one of a plurality of light-emitting units (see FIG. 4) in accordance with the control signal.

Optical transmitter module 50 includes a thermoelectric cooler (TEC) 48 that controls the temperatures of a plurality of light-emitting devices arranged in optical transmitter module 50. Thermoelectric cooler 48 can be configured by a Peltier device. Temperature control IC 46 transmits a control signal to thermoelectric cooler 48 for controlling the temperature of thermoelectric cooler 48. As described below, one thermoelectric cooler (TEC) 48 is provided in common to the plurality of light-emitting devices (laser diodes) inside optical transmitter module 50.

Optical receiver module 60 receives an optical signal and converts the optical signal into an electric signal. The electric signal from optical receiver module 60 is transmitted to clock data recovery IC 44. Clock data recovery IC 44 is not limited to be built in optical transceiver 111 and may be provided outside of optical transceiver 111 and on host board 1.

A clock data recovery IC on the transmitter and a clock data recovery IC on the receiver may be provided separately. Each IC may be built in optical transceiver 111 or may be provided outside of optical transceiver 111 and on host board 1.

FIG. 4 is a block diagram schematically showing the configuration of optical transmitter module 50 shown in FIG. 3. As shown in FIG. 4, optical transmitter module 50 includes a temperature monitor 10, laser diodes 11, 12, 13, and 14, submounts 21, 22, 23, and 24, a driver 30, an optical wavelength multiplexer (optical MUX) 42, and a thermoelectric cooler 48. Optical transmitter module 50 may be an optical transmitter module of transmitter optical subassembly (TOSA) type.

Driver 30 supplies a drive current to each of laser diodes 11, 12, 13, and 14 in response to a signal from outside (e.g., clock data recovery IC 44 shown in FIG. 3) of optical transmitter module 50. Each of laser diodes 11, 12, 13, and 14 is supplied with a current from driver 30 to output laser light. The center wavelength of the laser light differs among laser diodes 11, 12, 13, and 14.

Each of laser diodes 11, 12, 13, and 14 serving as the light-emitting units can change an oscillation wavelength in accordance with a corresponding one of the supplied drive currents. Laser diodes 11, 12, 13, and 14 may be, for example, distributed-feedback laser diodes (DFB-LDs), electroabsorption modulator integrated distributed-feedback laser diodes (EA-DFB-LDs), or semiconductor optical amplifier (SOA) integrated EA-DFB-LDs including integration of SOAs.

Optical wavelength multiplexer 42 multiplexes four optical signals, each of which is output from a corresponding one of laser diodes 11, 12, 13, and 14 and has a different wavelength. Optical wavelength multiplexer 42 outputs an optical signal having a plurality of wavelengths to an unshown optical fiber (PON line).

Laser diodes 11, 12, 13, and 14 are mounted on submounts 21, 22, 23, and 24, respectively. Submounts 21, 22, 23, and 24 are made of a material having a relatively high thermal conductivity. In one embodiment, submounts 21, 22, 23, and 24 are made of aluminum nitride (AlN).

Submounts 21, 22, 23, and 24 are in contact with thermoelectric cooler 48. Submounts 21, 22, 23, and 24 are separated from each other on the surface of thermoelectric cooler 48. Temperature monitor 10 monitors the temperature of the surface of thermoelectric cooler 48.

FIG. 5 is a schematic view for illustrating a thermal connection among the laser diode, submount, and thermoelectric cooler shown in FIG. 4. As shown in FIG. 5, each of submounts 21, 22, 23, and 24 is thermally connected to a corresponding laser diode and is thermally connected to thermoelectric cooler 48. Each of submounts 21, 22, 23, and 24 is a device having a thermal resistance. Laser diodes 11, 12, 13, and 14 are thermally isolated from each other.

Driver 30 (see FIG. 4) supplies drive currents I1, I2, I3, and I4 to laser diodes 11, 12, 13, and 14, respectively. Driver 30 can individually adjust drive currents I1, I2, I3, and I4. This individually adjusts the center wavelength of the laser light output from each of laser diodes 11, 12, 13, and 14. It suffices that in the adjustment of the wavelength, at least one of four laser diodes 11, 12, 13, and 14 changes the oscillation wavelength in accordance with the drive current.

In order to adjust the wavelength, not only the drive current but also the temperature of thermoelectric cooler 48 may be adjusted. In the present embodiment, driver 30 and submounts 21, 22, 23, and 24 are configured to individually adjust the wavelength of the optical signal per light-emitting unit (laser diode).

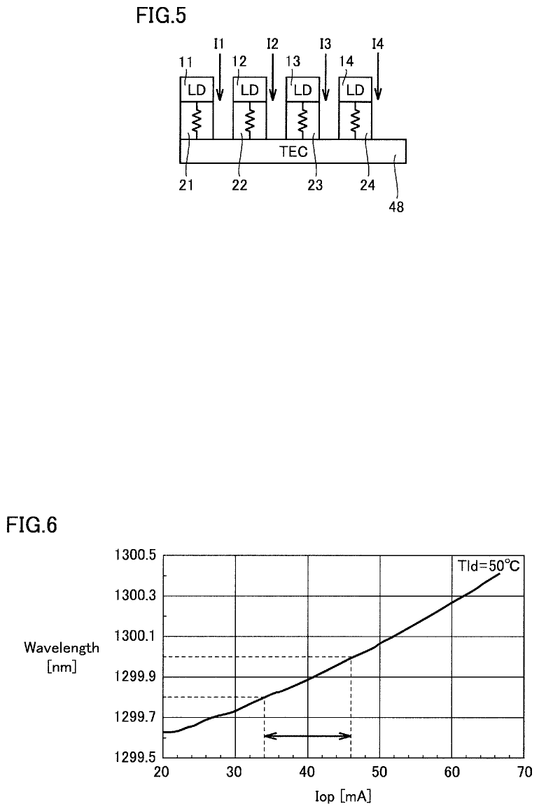

FIG. 6 shows an example relationship between the drive current and the center wavelength of laser light for a laser diode (DFB-LD) applicable to the present embodiment. As one example, FIG. 6 shows a relationship between drive current and center wavelength when a temperature Tld of the laser diode is 50° C. FIG. 6 shows an example range of a drive current Iₒₚ that can be adjusted from the viewpoints of characteristics at 25.8 Gbps and reliability assurance. For example, within a range of drive current Iₒₚ from 32 mA to 46 mA, the center wavelength can be changed from 1299.8 nm to 1300.0 nm. A drive current for outputting an optical signal having a desired wavelength can be determined from the range of drive current Lₒₚ. That is to say, the operating point of the laser diode is determined. FIG. 6 shows example characteristics of any one of laser diodes 11 to 14. Also for the remaining laser diodes of laser diodes 11 to 14, the center wavelength can be changed in accordance with a drive current through the center wavelength varies.

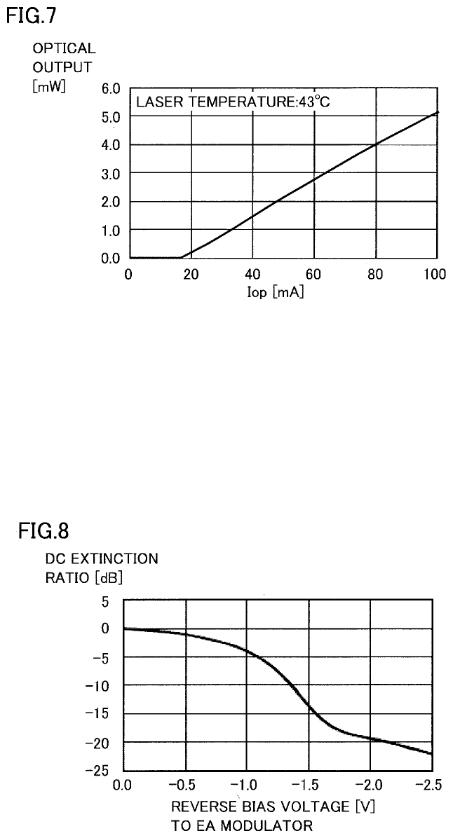

For the DFB-LD, when an operating point is changed by changing the drive current, optical output power changes as well. This may vary optical output power. Contrastingly, in an embodiment in which EA-DFB-LDs are used as laser diodes 11, 12, 13, and 14, for example, even when optical output power increases by changing the drive current of the DFB-LD portion as shown in FIGS. 7 and 8, the light absorption amount of the EA modulator can be increased by changing the bias level of the EA modulator. This corrects optical output power so as to reduce the optical output power in the EA modulator. Although the change in the bias level of the EA modulator does not contribute to the change in wavelength, an optical wavelength may change more or less. Thus, a duty ratio of the modulation signal output of driver 30 is preferably changed as well.

Similarly, when laser diodes 11, 12, 13, and 14 are SOA integrated EA-DFB-LDs, the wavelength can be adjusted by a current supplied to the DFB-LD portion, and optical output power can also be adjusted in the EA portion and the SOA portion. The embodiment in which SOA integrated EA-DFB-LDs are used as laser diodes 11, 12, 13, and 14 enables more flexible adjustment, thereby extending the wavelength adjustment range.

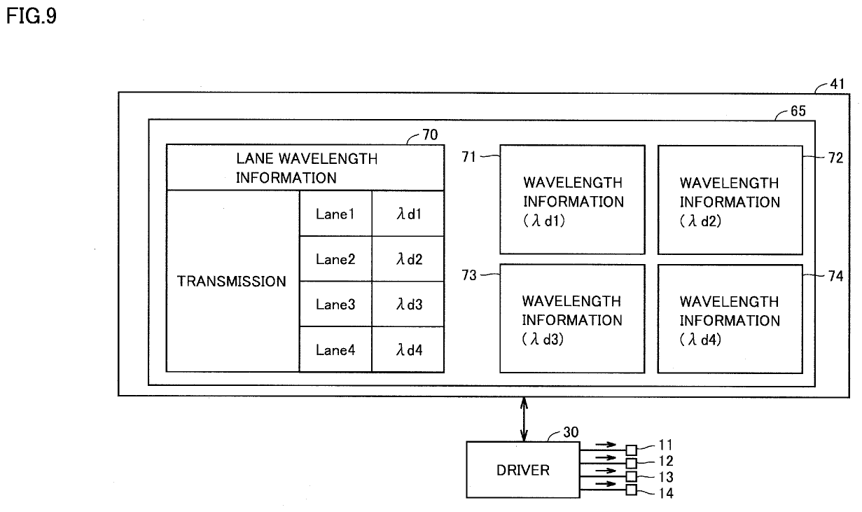

FIG. 9 is a block diagram showing an example configuration of a controller of an optical transceiver. As shown in FIG. 9, controller 41 can include a storage unit 65. Storage unit 65 may be provided in the optical transceiver separately from controller 41.

Storage unit 65 can store lane information 70 and pieces of wavelength information 71 to 74. Lane information 70 is information that associates four lanes (channels), namely, lane 1, lane 2, lane 3, and lane 4 with wavelengths (λd1, λd2, λd3, λd4) of the optical signals transmitted through the respective lanes. Transmission wavelengths λd1, λd2, λd3, and λd4 are wavelengths of the optical signals transmitted from laser diodes 11, 12, 13, and 14, respectively. The pieces of wavelength information 71 to 74 pertain to transmission wavelengths λd1, λd2, λd3, and λd4, respectively, and correspond to pieces of information about the operating points of laser diodes 11 to 14.

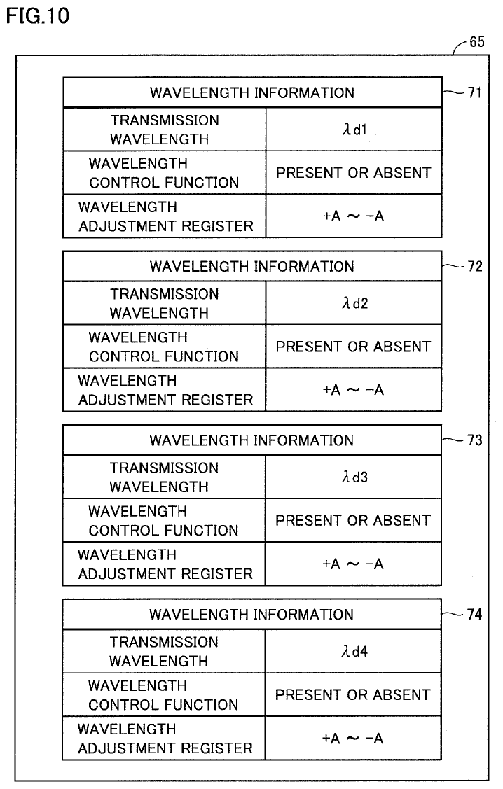

FIG. 10 shows an example of wavelength information. As shown in FIG. 10, each of the pieces of wavelength information 71 to 74 includes transmission wavelength information (λd1, λd2, λd3, λd4), information (e.g., flag) indicating whether a wavelength control function is valid or invalid, and a wavelength adjustment register. The wavelength adjustment register receives any value of, for example, +A to −A (A is a positive integer) and holds the value. An adjustment width of the transmission wavelength is determined by the value written in the wavelength adjustment register. For example, the transmission wavelength changes 0.05 nm every time the register value is changed by one level. The value of the wavelength adjustment register is linked to a change amount of the temperature of the laser diode or a change amount of the drive current of the laser diode.

When the wavelength control function is set to be valid in one piece of wavelength information, controller 41 can adjust the transmission wavelength specified by this wavelength information. Controller 41 determines the operating point of a corresponding laser diode of laser diodes 11 to 14 based on a value written in the wavelength adjustment register. Controller 41 controls the drive current of the laser diode in accordance with the operating point. Driver 30 accordingly controls the drive current of the laser diode. Controller 41 may further control the temperature of thermoelectric cooler 48. It suffices that storage unit 65 stores only the information about a wavelength to be changed among wavelengths λd1, λd2, λd3, and λd4. Storage unit 65 thus stores at least one piece of wavelength information.

For example, the specifications of the zero-dispersion wavelength of a single mode fiber shown in ITU-TG.652 are defined as 1300 nm to 1324 nm. The transmission wavelength in 100 GbE is defined as follows: λ1=1295.56 nm (1294.53 nm to 1296.59 nm), λ2=1300.05 nm (1299.02 nm to 1301.09 nm), λ3=1304.58 nm (1303.54 nm to 1305.63 nm), and λ4=1309.14 nm (1308.09 nm to 1310.19 nm).

Four-wave mixing occurs strongly when the zero-dispersion wavelength of the optical fiber coincides with the transmission wavelength and a phase matching condition between wavelengths is satisfied. It is known that when input light has a frequency (fi, fj, fk), the frequency of the resultant light is (fi+fj−fk). Conceivably, the zero-dispersion wavelength of the single mode fiber is distributed around 1312 nm, which is the center between 1300 nm and 1324 nm in the specifications. In the wavelength arrangement in 100 GbE, thus, wavelength λ4 has the highest probability that it will coincide with the zero-dispersion wavelength of the optical fiber, and wavelength λ3 has the second highest probability that it will coincide with the zero-dispersion wavelength of the optical fiber.

When the wavelengths of four optical signals are arranged equidistantly, the wavelength of the light generated through four-wave mixing is identical to the wavelength of signal light. The transmitter thus cannot remove the wavelength by an optical bandpass filter before O/E conversion. The reception characteristics on the receiver are accordingly affected. Particularly when the wavelength of the light generated through four-wave mixing is very close to the wavelength of the signal light, the light generated through four-wave mixing is coherent crosstalk noise. The receiver cannot remove the coherent crosstalk noise by the optical bandpass filter, as well as by a low pass filter after O/E conversion. Consequently, coherent crosstalk noise may cause significant degradation in reception characteristics.

A case in which, for example, wavelength λ3 coincides with the zero-dispersion wavelength is assumed here. Wavelengths λ_{FWM} that may enter the wavelength region same as the transmission wavelength region at the occurrence of four-wave mixing are as follows:

λ_{FWM}=λ3+λ3−λ2≈λ4

λ_{FWM}=λ3+λ3−λ4≈λ2

λ_{FWM}=λ4+λ2−λ3≈λ3

In the present embodiment, wavelengths λd1, λd2, λd3, and λd4 of four optical signals can be adjusted individually. The timings at which wavelengths λd1, λd2, λd3, and λd4 are adjusted are not particularly limited. In one embodiment, wavelengths λd1, λd2, λd3, and λd4 of four optical signals may be adjusted individually at the manufacturing stage.

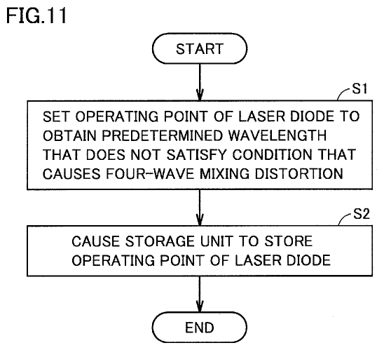

FIG. 11 is a flowchart illustrating a method of manufacturing an optical transmitter according to the present embodiment. The process shown in this flowchart may be performed at the stage of manufacturing an optical transmitter, or may be performed at the stage of combining an optical transmitter and an optical receiver to assemble an optical transceiver.

With reference to FIG. 11, at step S1, the operating points of laser diodes 11, 12, 13, and 14 are set such that the wavelength of an optical signal output from the laser diode is a predetermined wavelength at which an effect of a four-wave mixing distortion is not caused. It suffices that at least one of wavelengths λd1, λd2, λd3, and λd4 is adjusted as long as the occurrence of a four-wave mixing distortion can be avoided. Consequently, at least one operating point of the operating points of laser diodes 11, 12, 13, and 14 is adjusted if necessary.

In order to solve a problem of crosstalk noise due to four-wave mixing, for example, at least one adjustable wavelength of a plurality of wavelengths may be first adjusted roughly, and then, an effect of crosstalk due to four-wave mixing may be determined for the plurality of wavelengths. For example, optical transceiver monitoring control block 20 on host board 1 may receive the values of wavelengths λd1, λd2, λd3, and λd4 and determine whether the four wavelengths satisfy a condition that causes a four-wave mixing distortion. If it is determined that the condition that causes a four-wave mixing distortion is satisfied, the value of at least one of wavelengths λd1, λd2, λd3, and λd4 may be changed and a determination process may be performed. If an effect of crosstalk due to four-wave mixing may occur, at least one adjustable wavelength may be adjusted again (adjusted finely) in consideration of such a combination of wavelengths as to reduce the above possibility.

At step S2, storage unit 65 is caused to store the operating point of the laser diode determined in the process of step S1. That is to say, the optical transmitter and the optical transceiver hold the information about the operating point of the laser diode. Storage unit 65 may store the values of drive currents I1, I2, I3, and I4 respectively associated with wavelengths λd1, λd2, λd3, and λd4 determined in the process of step S1.

The value of at least one of wavelengths λd1, λd2, λd3, and λd4 stored in storage unit 65 may be changed in use of optical transceiver 111. This allows adjustment of the wavelength of the optical signal such that a four-wave mixing distortion does not occur in the use of optical transceiver 111.

As described above, in the embodiment of the present embodiment, a plurality of light-emitting units (laser diodes 11 to 14) that transmit optical signals having different wavelengths are included, and at least one light-emitting unit of the plurality of light-emitting units is configured to adjust the wavelength. Consequently, an optical transmitter configured to cause no four-wave mixing distortion can be achieved. Further, the embodiment of the present invention can achieve an optical transceiver including an optical transmitter capable of reducing a possibility of occurrence of a four-wave mixing distortion. Further, the embodiment of the present invention can manufacture an optical transmitter capable of reducing a possibility of occurrence of a four-wave mixing distortion and an optical transceiver including the optical transmitter.

A possibility of occurrence of a four-wave mixing distortion can be reduced in the use of an optical transmitter (optical transceiver). Consequently, degradation in reception characteristics can be prevented on the side on which an optical signal is received.

A laser diode chip is usually designed and manufactured to emit light with a desired wavelength. The resultant laser diode chip, however, does not necessarily have an emission wavelength as designed, and the emission wavelength may vary in a relatively wide range of the specifications. The embodiment of the present invention can control the temperature from each laser diode by thermoelectric cooler 48 and a thermal resistor (a corresponding submount of submounts 21 to 24). This can adjust the wavelength such that an effect of a four-wave mixing distortion does not occur after assembly of the optical transmitter.

Further, the optical transmitter can store the information about the adjusted wavelength. The optical transmitter stores the information about the wavelength, thus acquiring the information about the wavelength of an optical signal from the optical transmitter through the interface. When the optical transmitter does not have the information about the wavelength, in order to acquire the information about the wavelength, the wavelength of light, which is actually output from the optical transmitter, needs to be measured. The embodiment of the present invention can acquire information about the wavelength of an optical signal without the need for actually outputting light from the optical transmitter.

The embodiment of the present invention is applicable to an optical transmission system including light-emitting units each outputting a corresponding one of a plurality of optical signals having a different wavelength. In the present embodiment, thus, the optical transceiver is not limited to a four-wavelength optical transceiver, as illustrated below. The present invention is not limited to a configuration in which at least three pieces of wavelength information are acquired from one optical transceiver, and the information about at least three wavelengths may be acquired from a plurality of optical transceivers.

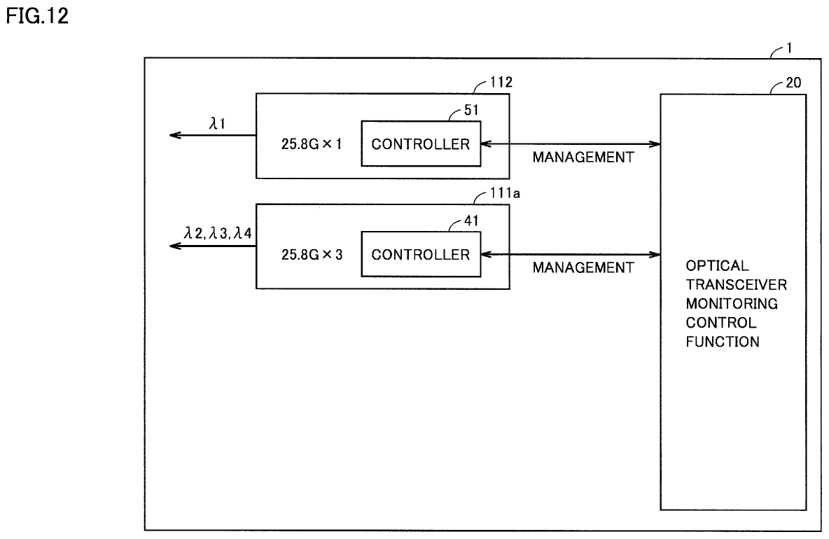

FIG. 12 is a schematic view showing one example configuration of a host board according to the present embodiment. As shown in FIG. 12, optical transceivers 112 and 111a are mounted on host board 1. Optical transceiver 111a is a three-wavelength optical transceiver and outputs an optical signal with wavelengths λ2, λ3, and λ4. Optical transceiver 112 outputs an optical signal having a wavelength λ1. Although not shown, an optical wavelength multiplexer receives respective optical signals from optical transceivers 112 and 111a and generates a wavelength-multiplexed optical signal. Three wavelengths of optical transceiver 111a may be any three of wavelengths λ1, λ2, λ3, and λ4.

Optical transceiver monitoring control block 20 reads information indicating wavelengths λ2, λ3, and λ4 from a controller 51 of optical transceiver 112 through the management interface. Optical transceiver monitoring control block 20 may read information indicating wavelength λ1 from controller 41 of optical transceiver 111a through the management interface. When each of optical transceivers 112 and 111a is plugged in host board 1, the information about a wavelength is transmitted from the optical transceiver to optical transceiver monitoring control block 20. The configurations of controllers 41 and 51 are similar to the configuration shown in FIG. 9, the description of which will not be repeated thereafter.

Optical transceiver monitoring control block 20 determines the presence or absence of an effect of a four-wave mixing distortion based on pieces of wavelength information from optical transceivers 112 and 111a. In the presence of an effect of a four-wave mixing distortion, optical transceiver monitoring control block 20 sends a control signal to controller 51 of optical transceiver 112 and adjusts wavelengths λ2, λ3, and λ4.

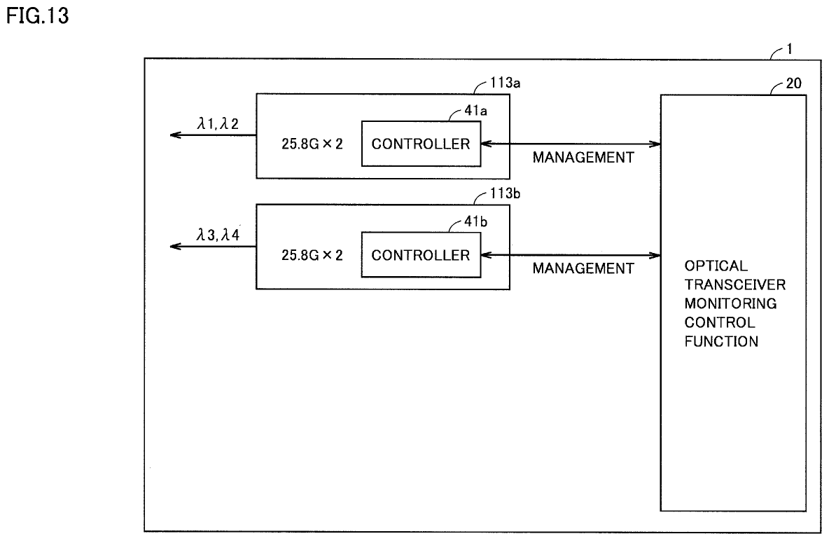

FIG. 13 is a schematic view showing another example configuration of the host board according to the present embodiment. As shown in FIG. 13, optical transceivers 113a and 113b are mounted on host board 1. Each of optical transceivers 113a and 113b is a two-wavelength optical transceiver. Optical transceiver 113a outputs an optical signal with wavelengths λ1 and λ2. Optical transceiver 113b outputs an optical signal with wavelengths λ3 and λ4. The combination of two wavelengths of optical transceivers 113a and 113b is not limited.

Optical transceiver monitoring control block 20 reads wavelength information indicating wavelengths λ1 and λ2 from a controller 41a of optical transceiver 113a through the management interface. Similarly, optical transceiver monitoring control block 20 reads wavelength information indicating wavelengths λ3 and λ4 from controller 41b of optical transceiver 113b through the management interface. The configurations of controllers 41a and 41b are similar to the configuration shown in FIG. 9, description of which will not be repeated thereafter.

Optical transceiver monitoring control block 20 determines the presence or absence of an effect of a four-wave mixing distortion based on pieces of wavelength information from optical transceivers 113a and 113b. In the presence of an effect of a four-wave mixing distortion, optical transceiver monitoring control block 20 sends control signals to controllers 41a and 41b and adjusts wavelengths λ2, λ3, and λ4.

The embodiments disclosed herein should be considered illustrative in every respect, not limitative. The scope of the present invention is defined not by the above-described embodiments but by the claims. It is intended that the scope of the present invention includes any modification within the scope and meaning equivalent to the scope of the claims.

### REFERENCE SIGNS LIST

1 host board, 10 temperature monitor, 11, 12, 13, 14 laser diode, 20 optical transceiver monitoring control block, 21, 22, 23, 24 submount, 30 driver, 41, 41a, 41b, 51 controller, 42 optical wavelength multiplexer, 43 electrical interface, 44 clock data recovery IC, 45 power supply IC, 46 temperature control IC, 48 thermoelectric cooler, 50 optical transmitter module, 60 optical receiver module, 65 storage unit, 70 lane information, 71-74 wavelength information, 111, 111a, 112, 113a, 113b optical transceiver, 200 management device, 300 PON system, 301 optical line terminal, 302 optical network unit, 303 PON line, 304 optical splitter, 305 trunk optical fiber, 306 branch optical fiber, S1, S2 step.

1. An optical transmitter comprising a plurality of light-emitting units each configured to transmit an optical signal having a different wavelength,
at least one light-emitting unit of the plurality of light-emitting units being configured to adjust the wavelength.

2. The optical transmitter according to claim 1, further comprising:
a thermoelectric cooler provided in common to the plurality of light-emitting units and configured to control temperatures of the plurality of light-emitting units;
a plurality of thermal resistors thermally connected to the thermoelectric cooler, each of the plurality of thermal resistors being thermally connected to a corresponding one of the plurality of light-emitting units; and
a current supply unit configured to individually supply a drive current to the plurality of light-emitting units.

3. The optical transmitter according to claim 2, wherein each of the plurality of thermal resistors is a submount on which a corresponding one of the plurality of light-emitting units is mounted.

4. The optical transmitter according to claim 2, wherein the current supply unit is configured to receive a control signal through an interface and change an operating point of the at least one light-emitting unit configured to adjust the wavelength.

5. The optical transmitter according to claim 1, further comprising an interface for outputting, to outside of the optical transmitter, wavelength information about the wavelength of the optical signal to be output from the at least one light-emitting unit configured to adjust the wavelength.

6. The optical transmitter according to claim 1, further comprising a storage unit configured to store an operating point of the at least one light-emitting unit configured to adjust the wavelength.

7. An optical transceiver comprising:
an optical transmitter according to claim 1; and
an optical receiver.

8. A method of manufacturing an optical transmitter including a plurality of light-emitting units each configured to transmit an optical signal having a different wavelength, at least one light-emitting unit of the plurality of light-emitting units being configured to adjust the wavelength, the method comprising:
setting an operating point of the at least one light-emitting unit configured to adjust the wavelength such that the wavelength of the optical signal output from each of the plurality of light-emitting units is excluded from a condition that causes a four-wave mixing distortion; and
causing the optical transmitter to store the operating point set in the setting.

9. An optical transmitter comprising:
a plurality of light-emitting units each configured to transmit an optical signal having a different wavelength, at least one light-emitting unit of the plurality of light-emitting units being configured to adjust the wavelength; and
a storage unit configured to store an operating point of the at least one light-emitting unit configured to adjust the wavelength for excluding, from a condition that causes a four-wave mixing distortion, the wavelength of the optical signal output from each of the plurality of light-emitting units.
